(19) United States
(12) Patent Application Publication
(10) Pub. No.: US 2025/0291091 A1
(43) Pub. Date: Sep. 18, 2025

(54) EMBEDDED LENS STRUCTURES AND THE METHODS OF FORMING THE SAME

(71) Applicant: Taiwan Semiconductor Manufacturing Co, Ltd., Hsinchu (TW)

(72) Inventors: Yu-Wei Shao, Taoyuan City (TW); Pei-Wen Huang, New Taipei City (TW); Ping-Jung Wu, Hsinchu (TW); Ming-Fa Chen, Taichung City (TW); Tsang-Jiuh Wu, Hsinchu (TW)

(21) Appl. No.: 18/772,943

(22) Filed: Jul. 15, 2024

Related U.S. Application Data
(60) Provisional application No. 63/565,098, filed on Mar. 14, 2024.
(60) Provisional application No. 63/650,542, filed on May 22, 2024.

(51) Int. Cl. G02B 3/00

(52) U.S. Cl. CPC G02B 3/0037; G02B 3/0025

(57) ABSTRACT

A method includes forming sacrificial blocks on a substrate, reflowing the sacrificial blocks, performing a first etching process to etch both of the sacrificial blocks and the substrate until parts of the substrate that are etched to form micro lenses, forming a patterned etching mask, and performing a second etching process to etch the substrate. At a time after both of the first etching process and the second etching process have been performed, the micro lenses are in recesses of the substrate.

### PRIORITY CLAIM AND CROSS-REFERENCE

This application claims the benefit of the following provisionally filed U.S. patent application: Application No. 63/650,542, filed on May 22, 2024, and entitled “EMBEDDED Si LENS STRUCTURE FORMATION FOR UNIFORMITY,” and provisionally U.S. patent application: Application No. 63/565,098, filed on Mar. 14, 2024, and entitled “EMBEDDED Si LENS STRUCTURE FORMATION FOR UNIFORMITY,” which applications are hereby incorporated herein by reference.

### BACKGROUND

Electrical and optical signaling and processing are techniques for signal transmission and processing. Optical signaling and processing have been used in increasingly more applications in recent years, and have been typically combined with electrical signaling and processing to provide full-fledged applications. Packages thus may include both of optical (photonic) dies including optical devices and electronic dies including electronic devices.

Micro lenses are used for converging optical signal. Micro lenses may be formed by etching a transparent substrate, so that the surfaces of the etched portions of the transparent substrate are rounded.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4A, 4B, 5A, 5B, 6-8, 9A, 9B, and 9C illustrate the views of intermediate stages in the formation of micro lens in accordance with some embodiments.

FIGS. 10-13A, 13B, 14A and 14B illustrate the views of intermediate stages in the formation of micro lens in accordance with alternative embodiments.

FIG. 15 illustrates a photonic package including a micro lens in accordance with some embodiments.

FIG. 16 illustrates a process flow for forming micro lenses in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A micro lens structure and the method of forming the same are provided. In accordance with some embodiments of the present disclosure, the micro lens may be formed from a transparent substrate such as a silicon substrate. The formation process may include two etching processes, with one etching process used for forming recesses in the substrate. The other etching process is used to form the micro lenses, which are located inside the recesses and thus are embedded in the substrate. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

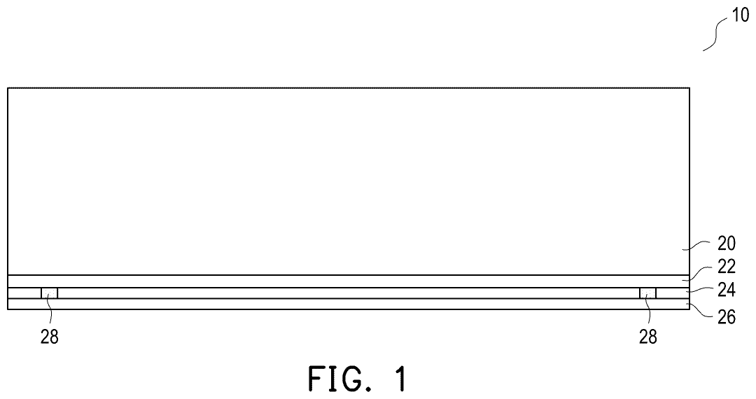

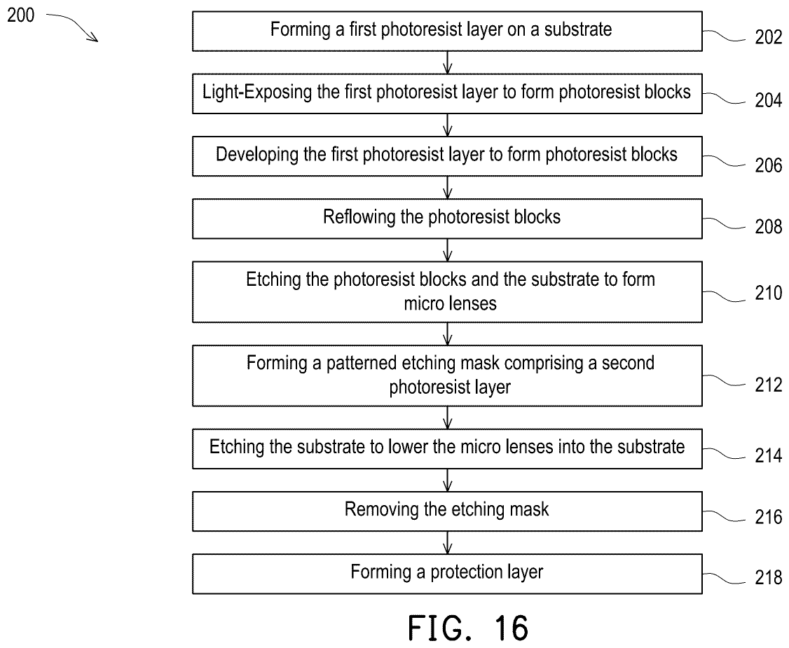

FIGS. 1-8, 9A, 9B, and 9C illustrate the cross-sectional views of intermediate stages in the formation of micro lenses in accordance with some embodiments of the present disclosure. The corresponding processes are also reflected schematically in the process flow 200 as shown in FIG. 16.

Referring to FIG. 1, wafer 10 is formed. Wafer 10 includes substrate 20. In accordance with some embodiments, wafer 10 is free from integrated circuit devices therein. For example, wafer 10 may not include any active devices (such as transistors) and passive devices (such as resistors, capacitors, inductors, or the like) therein. Substrate 20 may be a blanket transparent substrate formed of a homogeneous material such as silicon (doped or undoped), and there is no metal region, dielectric region, etc., therein.

In accordance with alternative embodiments, wafer 10 may be a device wafer that includes integrated circuit devices therein. For example, wafer 10 may include active devices such as transistors and passive devices such as resistors, capacitors, inductors, or the like therein. The active devices may be formed at the bottom surface of substrate 20, and additional features such as metal lines and dielectric layers may be formed under substrate 20 and electrically connecting to the integrated circuit devices. Passive devices may also be formed in the dielectric layers, and may or may not extend from the dielectric layers into substrate 20.

In subsequent discussion, it is assumed that wafer 10 is a blanket wafer that is free from active devices and passive devices therein. The discussion may also be applied to a device wafer when the micro lenses are to be formed directly in the semiconductor substrate of a device wafer.

Wafer 10 may include a plurality of dielectric layers such as layers 22, 24, and 26. In accordance with some embodiments, layer 22 may be formed of or comprise a dielectric material, which may be an oxide-based material such as silicon oxide, phospho-silicate glass (PSG), borosilicate glass (BSG), boron-doped phospho silicate glass (BPSG), fluorine-doped silicate glass (FSG), or the like. Layer 22 may be formed using spin coating, Flowable Chemical Vapor Deposition (FCVD), or the like. In accordance with alternative embodiments of the present disclosure, layer 22 is formed by oxidizing a surface layer of substrate 20 to form a thermal oxide layer. In accordance with some embodiments, the entire layer 22 is formed of a homogeneous material, with no other material different from the homogeneous material therein.

Layer 24 may be formed of or comprise a dielectric material, which may be a nitride-based material such as silicon nitride, while it may also be formed of or comprise other materials such as silicon oxynitride (SiON).

In accordance with some embodiments, layer 26 is formed of or comprises a dielectric material, which may be an oxynitride based material such as silicon oxynitride (SiON), while it may also be formed of or comprises other materials such as silicon oxide, silicon oxycarbide (SiOC), silicon carbo-nitride (SiCN), or the like.

Alignment marks 28 may be formed in dielectric layers 22, 24, and/or 26, for example, in dielectric layer 24. In accordance with some embodiments, alignment marks 28 comprise a metal, a metal alloy, a metal compound, etc., to increase the contrast of alignment marks 28 relative to the surrounding materials. In accordance with some embodiments, alignment marks 28 comprise metal regions formed of or comprising copper, a copper alloy, tungsten, nickel, and/or the like. An adhesion layer may or may not be formed underlying and lining the metal regions. The adhesion layer may be formed of or comprise titanium, titanium nitride, tantalum, tantalum nitride, or the like.

The formation process of alignment marks 28 may include etching the respective dielectric layer (such as dielectric layer 24) to form openings, depositing the adhesion layer (if formed) as a conformal layer, for example using Physical Vapor Deposition (PVD), depositing the metallic material over the adhesion region, and then performing a Chemical Mechanical Polish (CMP) process to remove excess portions of the adhesion layer and the metallic material, leaving alignment marks 28 in dielectric layer 24.

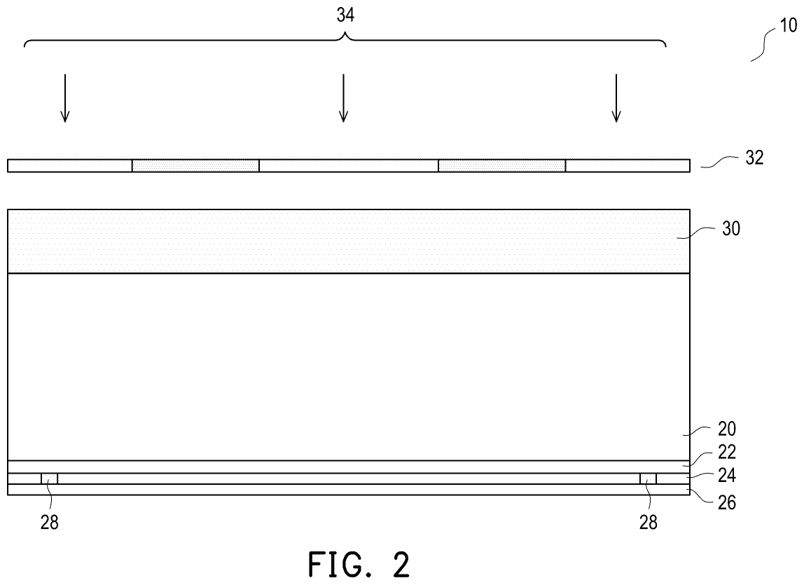

Referring to FIG. 2, a photoresist layer 30 is coated on substrate 20. The respective process is illustrated as process 202 in the process flow 200 as shown in FIG. 16. In accordance with some embodiments, the photoresist layer 30 is formed of a material that is capable of being reflowed at an elevated temperature. After the coating of photoresist layer 30, photoresist layer 30 is soft baked to drive out solvents and hardened.

In accordance with some embodiments, before photoresist layer 30 is coated, an entire top surface of substrate 20 is exposed, and there is no additional layer and material such as oxide layer contacting the top surface of substrate 20. There is also no deposited layer between photoresist layer 30 and substrate 20. In accordance with some embodiments, before photoresist layer 30 is coated, a cleaning process may be performed to remove any nature oxide on the top surface of substrate 20. The coated photoresist layer 30 may be on the exposed top surface of substrate 30, with no oxide in between. The cleaning process may be performed through a dry etching process, and the coating of photoresist layer 30 may also be performed in a same vacuum chamber in which the cleaning process is performed, with no vacuum break in between.

In accordance with alternatively embodiments, a nature oxide layer may be before photoresist layer 30 and substrate 20, and there is no other layer deposited on substrate 20 and between photoresist layer 30 and substrate 20. The thickness of the of the nature oxide layer, if existing, may have a thickness smaller than about 2 nm.

Lithography mask 32 is placed over the photoresist layer 30. Lithography mask 32 includes a plurality of opaque portions and a plurality of transparent portions. A light-exposure process is performed to light-expose photoresist layer 30. The respective process is illustrated as process 204 in the process flow 200 as shown in FIG. 16. After the light-exposure process, the light-exposed photoresist layer 30 may or may not be hard baked. The position of lithography mask 32 may be aligned to the intended position of wafer 10 by using alignment mark 28.

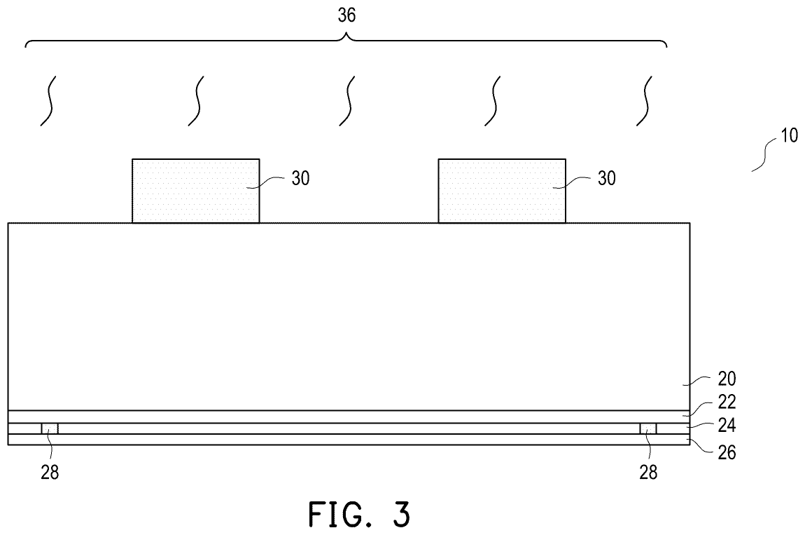

A development process is then performed to remove some portions (exposed or un-exposed, depending on whether photoresist 30 is positive or negative) of the photoresist layer 30. The resulting structure is shown in FIG. 3. The respective process is illustrated as process 206 in the process flow 200 as shown in FIG. 16. The remaining portions of photoresist layer 30 are referred to as photoresist blocks 30 hereinafter. Photoresist blocks 30 will be etched in subsequent process, and thus also act as, and are referred to as, sacrificial blocks 30. In accordance with some embodiments, photoresist blocks 30 are located in a repeating pattern such as an array, a beehive pattern, or the like. There may also be a single or a few photoresist blocks 30 formed.

Photoresist blocks 30, when viewed in a top view of the structure shown in FIG. 3, may have the same top-view shapes and the same top-view size. The top-view shapes may include circles, rectangles, hexagons, octagons, or the like. In accordance with some embodiments, the entire top surface of substrate 20 is coplanar, and the entire top surface of photoresist blocks 30 is coplanar, so that the photoresist blocks 30 at different portions of wafer 10 have the same thickness and thus the same volume.

Further referring to FIG. 3, a reflow process 36 is performed. The respective process is illustrated as process 208 in the process flow 200 as shown in FIG. 16. The reflow process is performed at an elevated temperature that is higher than the softening temperature of the photoresist blocks 30. In accordance with some embodiments, the reflow process 36 is performed at a temperature in a range between about 155° C. and about 165° C. The reflow process 36 may be performed, for example, for a duration in a range between about 305 seconds and about 345 seconds. The actual temperature and duration are related to the material of photoresist blocks 30, and may be higher/longer or lower/shorter.

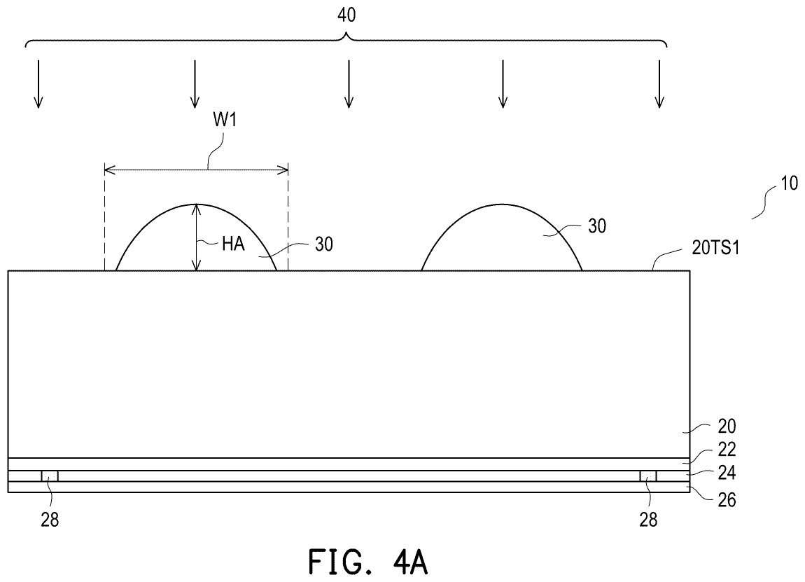

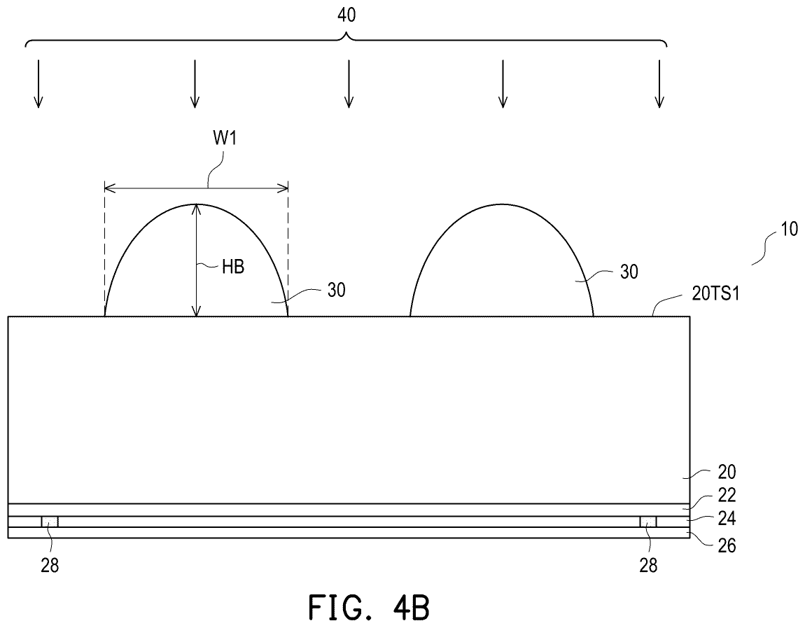

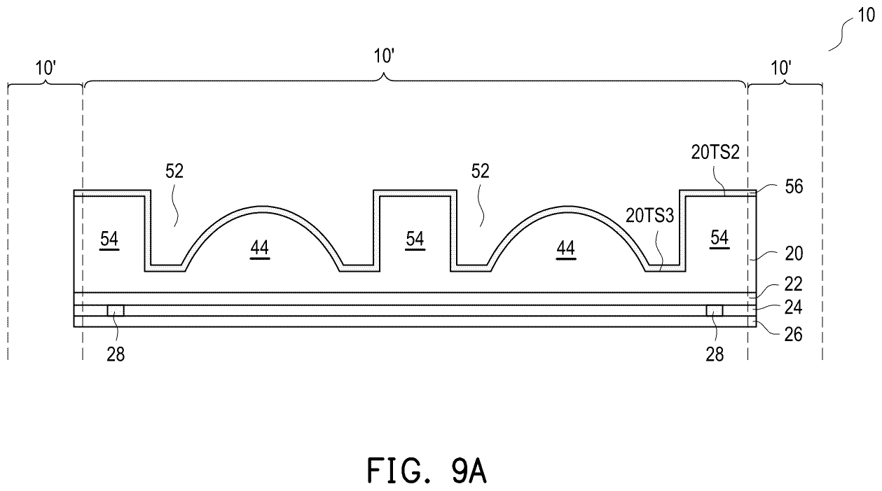

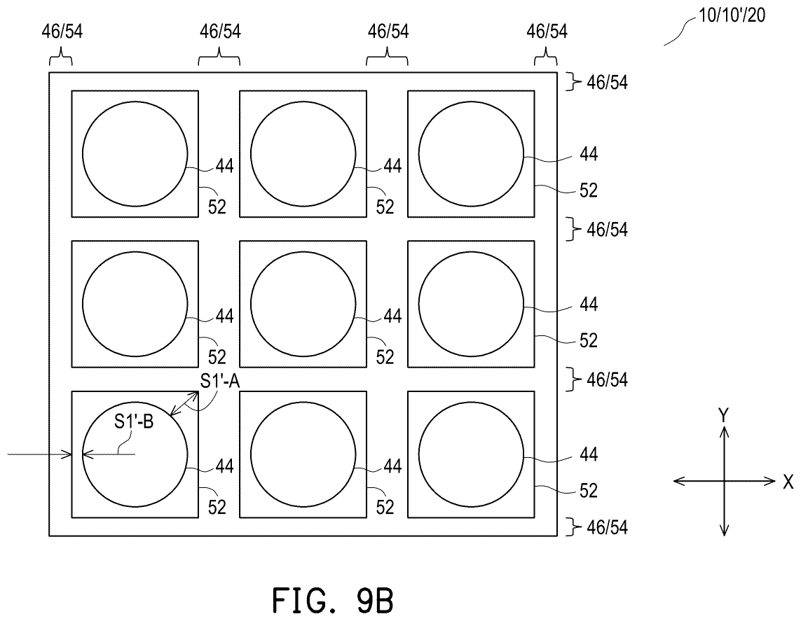

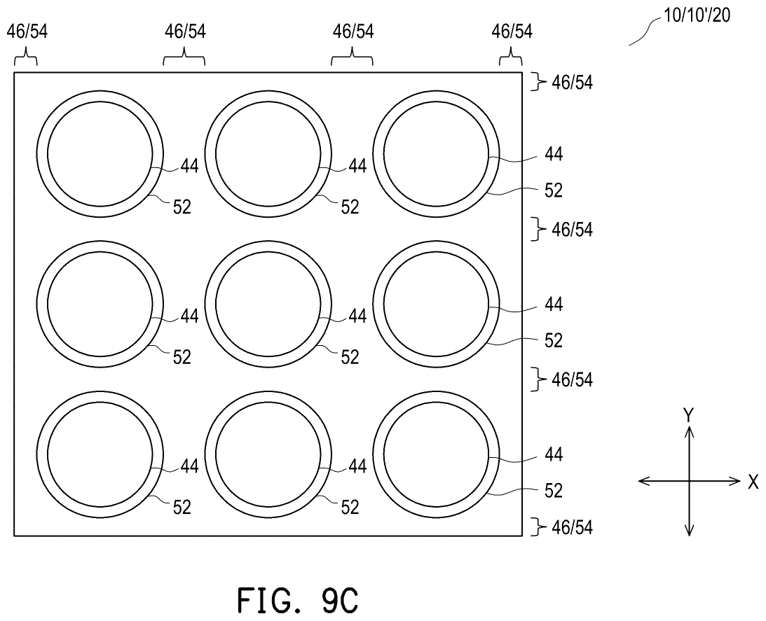

As a result of reflowing photoresist blocks 30, photoresist blocks 30 are molten, and are reshaped to have rounded or oval surfaces when viewed from side, as shown in FIGS. 4A and 4B, respectively. Throughout the description, the rounded shape refers to the shape whose width W1 is equal to or greater than two times the height HA (FIG. 4A). The oval shape refers to the shape whose width W1 is smaller than two times the height HB (FIG. 4A). When viewed from top, the reflowed photoresist blocks 30 may be rounded. The top-view shape of the reflowed photoresist blocks 30 may be essentially the same as the top-view shape of the to-be-formed micro lenses 44 as shown in FIG. 9B or 9C. The top-view size of the reflowed photoresist blocks 30 may be the same as or slightly greater than or smaller than the top-view shape of micro lenses 44 as shown in FIG. 9B. The lateral dimension W1 of the reflowing photoresist blocks 30 may be in the range between about 100 μm and about 120 μm. The lateral dimension W1 may be a diameter since the reflowing photoresist blocks 30 may have circular top-view shapes.

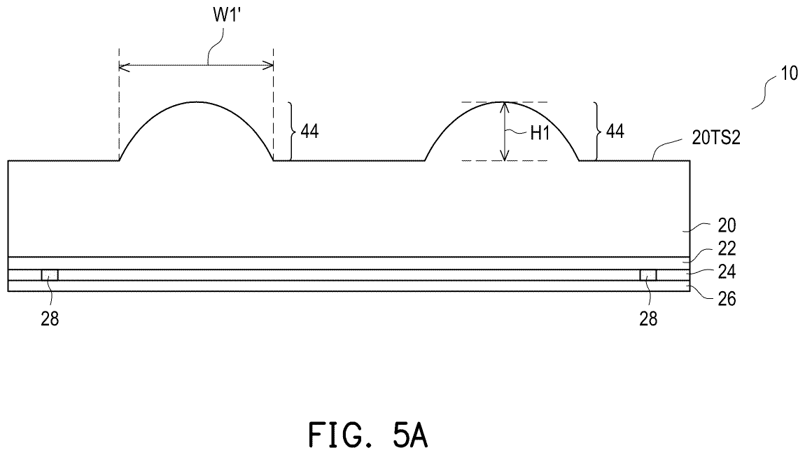

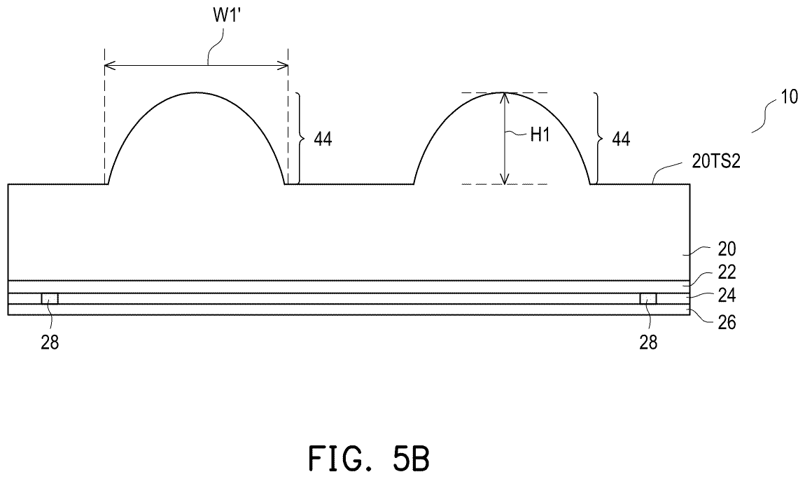

An etching process 40 is then performed, as shown in FIG. 4, to form micro lenses 44, which are shown in FIGS. 5A and 5B, in which micro lenses 44 have rounded shape or oval shape, respectively. The respective process is illustrated as process 210 in the process flow 200 as shown in FIG. 16. At the time the etching process 40 is started, the reflowed photoresist blocks 30 may be in physical contact with the material (such as silicon) of substrate 20. Alternatively, a very thin nature oxide layer may exist between the reflowed photoresist blocks 30 and substrate 20, with no deposited layer(s) on the nature oxide layer.

Etching process 40 is an anisotropic etching process, which is performed by using an etching gas that attacks both of substrate 20 and the reflowed photoresist blocks 30. The etching rate ER30 of the reflowed photoresist blocks 30 and the etching rate ER20 of substrate 20 may also be close to each other. For example, the etching rate ratio ER20/ER30 may be in the range between about 0.8 and about 1.2, and may be in the range between about 0.9 and about 1.1. In accordance with some embodiments, the etching process 40 is performed using an etching gas comprising NF₃, CO, O₂, NF₃, CF₄, Cl₂, and/or the like.

With the proceeding of the etching process 40, both of the reflowed photoresist blocks 30 and the exposed portions of substrate 20 are etched down, with the surface shape and surface size being the same as the surface shape and the same as or slightly smaller than the size of the reflowed photoresist blocks 30. With the proceeding of the etching process, increasingly more surface portions of the reflowed photoresist blocks 30 are consumed, exposing the surface portions of substrate 20 that are directly underlying the edge portions of the reflowed photoresist blocks 30, and the exposed portions of substrate 20 are also etched. More and more portions of substrate directly under the reflowed photoresist blocks 30 are exposed and start to be etched. Accordingly, the shape and the surface profile of the reflowed photoresist blocks 30 is transferred into substrate 20.

As shown in FIG. 4, before the etching process 40 is started, substrate 20 has top surface 20TS1. The etching process 40 causes the reduction of the height of the planar top surface of substrate 20 to top surface 20TS2 as shown in FIG. 5. The top surfaces 20TS2 and 20TS1 have a height difference that is greater than the height H1 of micro lenses 44.

The etching process 40 is lasted until all of the reflowed photoresist blocks 30 are consumed. FIG. 5 illustrates a resulting structure. In accordance with some embodiments, the top surface of the etched substrate 20 are rounded, and hence forming micro lenses 44. When viewing in a side view(s), micro lenses 44 may have rounded, and possibly oval surfaces. Micro lenses 44 may form a repeating pattern such as an array or a beehive pattern. FIG. 9B or 9C illustrates a top view of a part of wafer 10, with some micro lenses 44 being illustrated. The lateral dimension W1′ (FIG. 5) of micro lenses 44, which may be diameters, may be the same as or slightly smaller than the width W1 (FIG. 4) of sacrificial blocks 30.

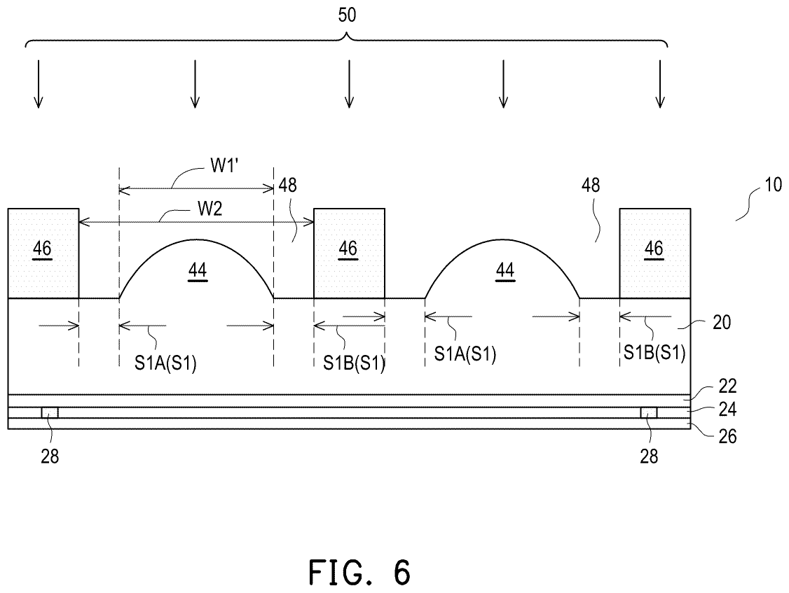

FIGS. 6 through 8 illustrate the process for lowering/sinking micro lenses 44 into substrate 20, so that the micro lenses 44 are protected. FIG. 6 illustrates the formation of etching mask 46, which comprises a second photoresist. The respective process is illustrated as process 212 in the process flow 200 as shown in FIG. 16. In accordance with some embodiments, etching mask 46 includes a single photoresist layer. In accordance with alternative embodiments, etching mask 46 has a dual-layer structure including a bottom anti-reflective coating and an overlying photoresist. In accordance with yet alternative embodiments, etching mask 46 has a tri-layer structure including a bottom layer, a middle layer, and a top layer formed of a photoresist. The etching mask 46 may include a patterned photoresist 46 in accordance with some embodiments, and hence is referred to as photoresist 46 hereinafter.

The material of photoresist layer 46 may be the same as, or different from, the material of photoresist 30. For example, one of photoresist layer 30 and photoresist 46 may be a positive photoresist, and the other may be a negative photoresist, or both of photoresist layer 30 and photoresist 46 may be positive photoresists or negative photoresists. The photoresist layer 30 and photoresist 46 may also have the same or different hardening temperatures. The patterned photoresist 46 has openings 48 therein. The centers of openings 48 may be aligned to (or offset to one side of) the centers of micro lenses 44, which is achieved by using alignment mark 28.

The lateral dimension W2 of the opening 48 in the patterned photoresist 46 may be in the range between about 110 μm and about 130 μm. The lateral dimension W2 is also greater than the width W1′ of micro lenses 44, for example, with the difference (W2−W1′) being greater than about 0.2 μm, greater than about 1 μm, greater than about 5 μm, and may be in the range between about 5 μm and about 20 μm. In accordance with some embodiments, spacings S1 may be equal to (W2−W1′)/2. Spacings S1 may be greater or smaller than (W2-W1′)/2 when the centers of micro lenses 44 are all offset to a same side (or different sides) of the respective centers of openings 48. For example, spacings S1A may be greater than spacings S1B. The lateral dimension W2 may be a length or a width when openings 48 have rectangular top-view shaped, or may be a diameter when the openings 48 have circular top-view shapes.

In accordance with some embodiments, the formation of patterned photoresist 46 includes coating a blanket photoresist, performing a soft baking process, performing a light exposure process using a lithography mask (not shown), and developing the exposed photoresist 46. A hard baking process may then be performed on the patterned photoresist 46. In the hard baking process, the patterned photoresist 46 is not reflowed, and maintains the shape as developed. This may be achieved, for example, by baking the patterned photoresist 46 and the underlying wafer 10 at a temperature that is lower than the softening temperature of photoresist 46. For example, the hard baking process may be performed at a temperature in a range between about 120° C. and about 140° C.

The top-view shape of the patterned photoresist 46 is discussed referring to FIG. 9B or 9C. In accordance with some embodiments in which micro lenses 44 are formed to have a pattern of an array, the patterned photoresist 46 may be formed as a grid. The grid includes horizontal portions (when viewed in the top view) having lengthwise directions in the X-direction and vertical portions having lengthwise directions in the Y-direction. The horizontal portions and the vertical portions of the patterned photoresist 46 are marked in accordance with some embodiments.

In accordance with alterative embodiments, in which micro lenses 44 are positioned to have other patterns other than array, the patterned photoresist 46 may be formed to have the corresponding patterns such as the beehive pattern.

Next, as also shown in FIG. 6, etching process 50 is performed to etch substrate 20, in which the patterned photoresist 46 is used as the etching mask. The micro lenses 44 are thus lowered into substrate 20. The respective process is illustrated as process 214 in the process flow 200 as shown in FIG. 16. The etching is performed using an anisotropic etching process. In accordance with some embodiments, the etching gas comprises fluorine (F₂), Chlorine (Cl₂), hydrogen chloride (HCl), hydrogen bromide (HBr), Bromine (Br₂), C₂F₆, CF₄, SO₂, the mixture of HBr, Cl₂, and O₂, the mixture of NF₃, HBr, Cl₂, O₂, CO, CH₂F₂, and/or the like.

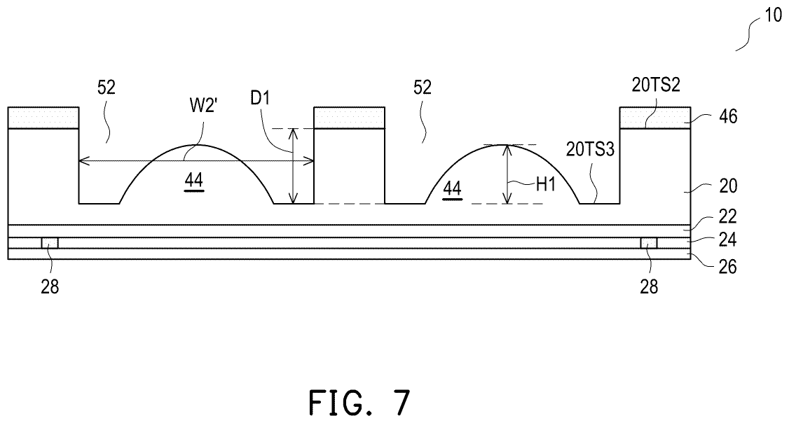

Due to the anisotropic etching, the exposed top surfaces of substrate 20, including the top surfaces of substrate 20 are uniformly reduced in height, hence forming the structure as shown in FIG. 7. Recesses 52 are thus formed in substrate 20. The recessing depth Di is greater than the height H1 of the micro lenses 44, so that the top ends of micro lenses 44 are lower than the top surface 20TS2 of substrate 20. The lateral dimension W2′ of the recesses 52 may be equal to or greater than width W2 (FIG. 6), and may be in the range between about 110 μm and about 130 μm.

In recesses 52, substrate 20 may include some portions (referred to as recess-bottom portions) directly underlying recesses 52 and aside of the micro lenses 44. The recess-bottom portions further have top surfaces 20TS3, which are further lower than the top surface 20TS2. The top surfaces 20TS3 may also be planar, or may be curved due to the etching and the shading of the photoresist 46. Different from the first etching process 40, after the second etching process 50, the photoresist 46, which may be thinned during the etching process 50, still has a bottom portion remaining.

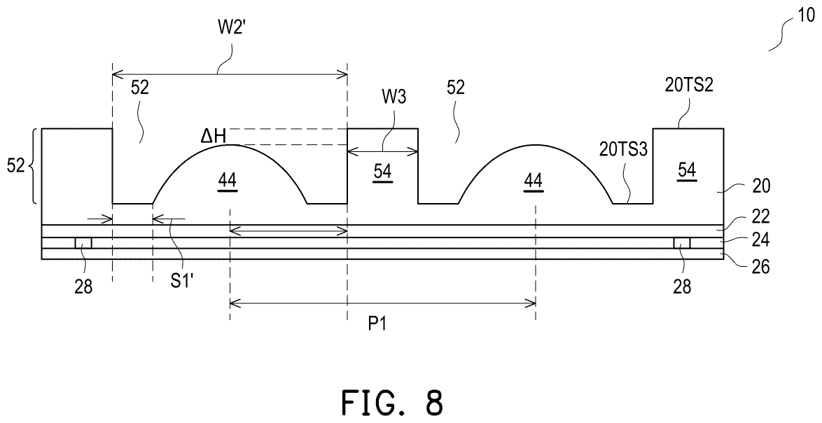

The remaining photoresist 46 is then removed, and the resulting structure is as shown in FIG. 8. The respective process is illustrated as process 216 in the process flow 200 as shown in FIG. 16. Micro lenses 44 are formed in the recesses 52 of substrate 20. Substrate 20 includes protection walls 54, which separate neighboring recesses 52 apart, and separate neighboring micro lenses 44 apart. In accordance with some embodiments, the top ends of micro lenses 44 are level with or lower than the top surface 20TS2 of the protection walls 54. In accordance with some embodiments, the height difference ΔH, which is the height difference between the topmost ends of micro lenses 44 and the top surface 20TS2, is greater than 0 μm and smaller than about 20 μm, or may be smaller than about 100 μm, or smaller than about 20 μm. With the difference ΔH being greater than 0 μm, the top ends of micro lenses 44 are recessed lower than the top surface 20TS2. Accordingly, when wafer 10 is flipped over and placed on other surfaces, micro lenses 44 will be higher than and spaced apart from the other surfaces, and will not be damaged.

The lateral dimension W2′ of the recesses 52 is smaller than the pitch P1 of micro lenses 44 to allow the space for the formation of protection walls 54. In accordance with some embodiments, the widths W3 of the protection walls 54 may be in the range between about 100 μm and about 300 μm. The spacings S1′ between the edges of micro lenses 44 and the corresponding nearest edges of protection walls 54 may be equal to or close to (for example, with less than 10 percent difference) spacings S1 (FIG. 6). Spacing S1′ may be greater than about 0.1 μm, and may be in the range between about 0.1 μm and about 5 μm, and may also be in the range between about 1 μm and about 5 μm.

FIG. 9A illustrates the formation of protection layer 56 in accordance with some embodiments. The respective process is illustrated as process 218 in the process flow 200 as shown in FIG. 16. Protection layer 56 may be formed of or comprise a transparent material such as silicon oxide, silicon oxy nitride, or the like. The formation process may include a conformal deposition process such as ALD, CVD, or the like. Alternatively, protection layer 56 may be formed through the thermal oxidation of substrate 20, for example, with silicon oxide being formed. A sawing process may then be formed to cut wafer 10 into dies 10′.

FIG. 9B illustrates a top view of a portion of wafer 10 and device 10′ in accordance with some embodiments. Recesses 52 are formed as discrete recesses that are separated from each other by protection walls 54. In accordance with some embodiments, due to the two etching processes, recesses 52 have top view shapes different from the top-view shapes than the micro-lenses 44. For example, recesses 52 may have square top-view shapes, while lenses 44 may have circular top-view shapes. In accordance with alternative embodiments, recesses 52 may have other top-view shapes including, and not limited to, circles, hexagons, octagons, or the like. As shown in FIG. 9B, the protection walls 54 form a grid, with recesses 52 being the grid openings of the grid. Micro lenses 44 are located at the centers of the recesses 52, or may be offset slightly to the same direction from the respective centers of the recesses 52.

In accordance with some embodiments, different portions of micro-lenses 44 may have different spacings from the nearest portions of the protection walls 54. For example, spacing S1′-A may be different from spacing S1′-B. Furthermore, recesses 52 may be concentric with the respective micro lenses 44 therein, as shown in FIG. 9B or 9C. Alternatively, the two etching processes make it possible to make the centers of recesses 52 to be eccentric with the centers of the respective micro lenses 44 therein.

FIG. 9C illustrates an embodiment in which recesses 52 also have circular top-view shapes. In accordance with some embodiments, micro lenses 44 have common centers with the respective recesses 52. Alternatively, the centers of recesses 52 may be slightly offset from the centers of the respective micro lenses 44 therein.

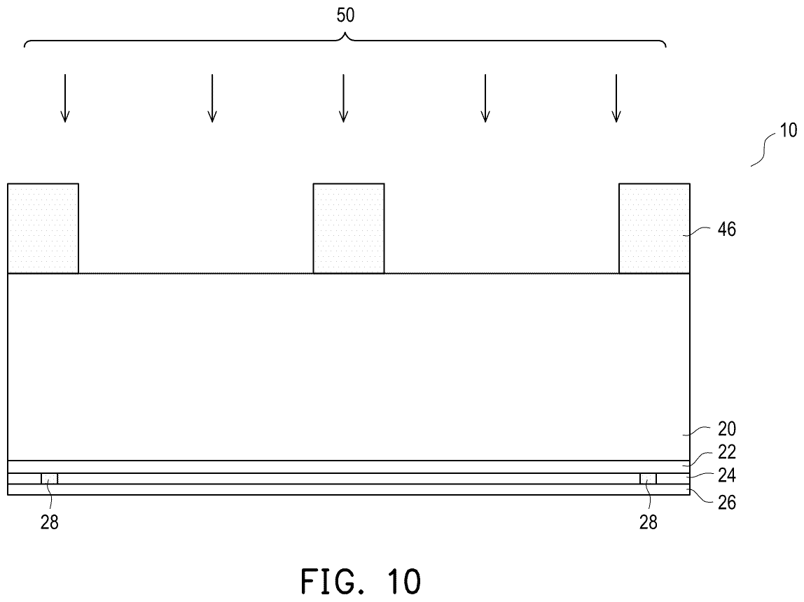

FIGS. 10 through 13 illustrate the formation of wafer 10 and die 10′ in accordance with alternative embodiments. These embodiments are essentially the same as that in the preceding embodiments, except that the order for forming micro lenses 44 and recesses 52 are inversed. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 10, wafer 10 is formed. The structure and the materials of wafer 10 are essentially the same as that are discussed referring to FIG. 1, and are not repeated herein. Next, the patterned etching mask 46 is formed over substrate 20. In accordance with some embodiments, the patterned etching mask 46 includes a photoresist, and may or may not include other layers under the photoresist. The formation process of the photoresist in the etching mask 46 may include spin-on coating a photoresist layer, performing a soft baking process to drive out the solvent therein and to harden the photoresist layer, and light-exposing and then developing the photoresist layer. After the development process, a hard baking process is performed. In the hard baking process, the photoresist is not reflowed. For example, the temperature adopted by the hard baking process may be lower than the softening temperature of the photoresist.

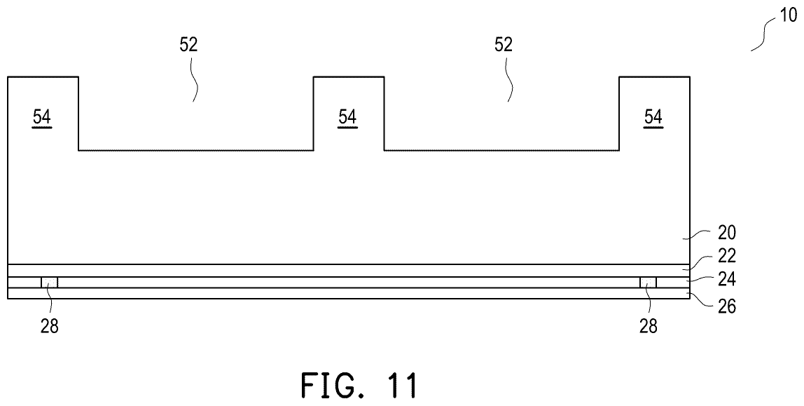

An etching process 50 is then performed to etch substrate 20, with the etching mask 46 defining patterns. Recesses 52 and protection walls 54 are thus formed. Etching mask 46 is then removed. The resulting structure is shown in FIG. 11. The sizes and the positioning of recesses 52 may be essentially the same as that discussed referring to FIGS. 9B and 9C. Accordingly, the top-view shapes of recesses 52 may have rectangular top-view shapes, circular top-view shapes, hexagonal top-view shapes, octagonal top-view shapes, or the like. The bottom surfaces of recesses 52 are planar, so that the subsequently formed micro lenses 44 may have the rounded and smooth surfaces as desired.

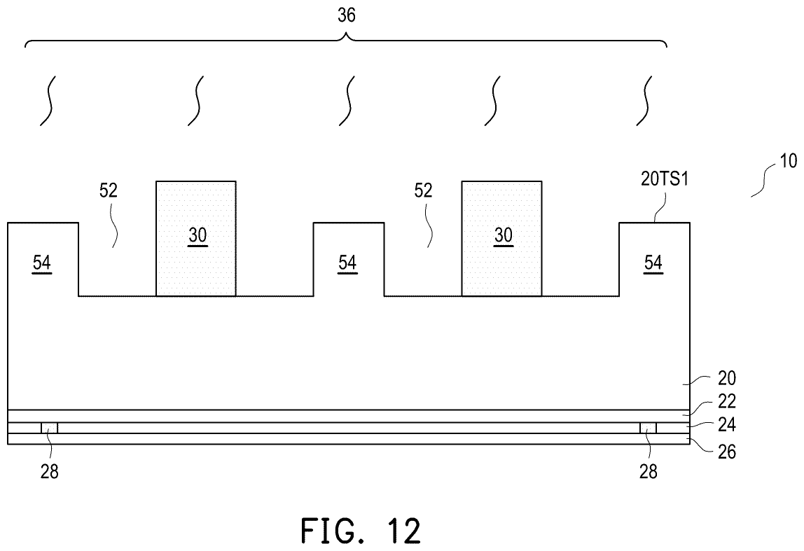

Referring to FIG. 12, photoresist blocks 30 are formed. In accordance with some embodiments, the formation process of photoresist blocks 30 may include spin-on coating a photoresist layer. Since photoresist blocks 30 are formed in recesses 52, at the time the photoresist layer finishes the spin-on coating, the top surface of the photoresist layer is higher than the top surface of the top surface 20TS1 of substrate 20 to allow the photoresist layer to flow to the entire wafer 10. The formation of photoresist blocks 30 further includes performing a soft baking process to drive out the solvent therein and to harden the photoresist layer, and light-exposing and then developing the photoresist layer.

The resulting photoresist blocks 30 also have top surfaces higher than the top surface 20TS1 of substrate 20. Since the top surfaces of the photoresist blocks 30 are relatively high comparing the top surface 20TS1, the widths (which may be diameters) of photoresist blocks 30 are controlled, so that after the subsequent reflow process, the widths of the reflowed photoresist blocks 30 have desirable values.

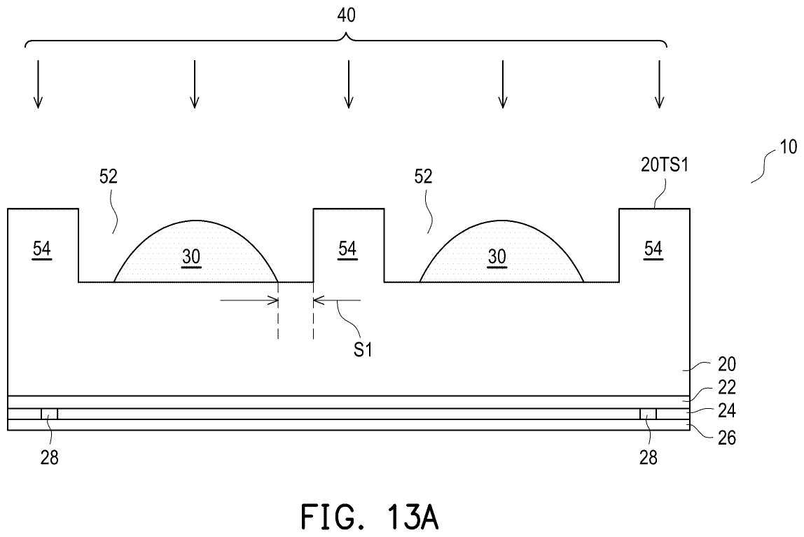

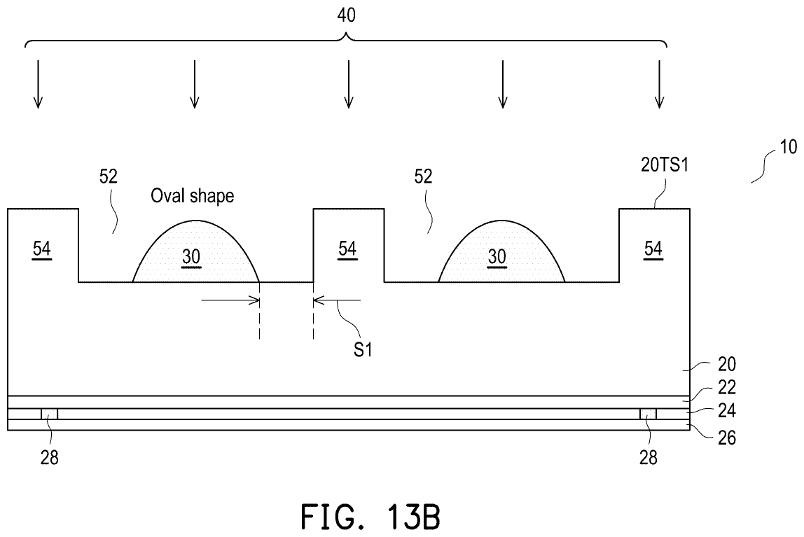

Further referring to FIG. 12, a reflow process 36 is performed. The resulting reflowed photoresist blocks 30 are illustrated in FIGS. 13A and 13B, respectively, in which photoresist blocks 30 have rounded shape and oval shape, respectively. The reflow process 36 is performed using a process condition that may cause the melting but does not cause the damage of the photoresist blocks 30. The process conditions may be the same as discussed in preceding embodiments, and are not repeated herein. After the melting and the solidifying, the reflowed photoresist blocks 30 have rounded top surfaces, and have rounded top-view shapes. When viewed from side, the reflowed photoresist blocks 30 may have round or oval surfaces. Furthermore, the reflowed photoresist blocks 30 are separated from the nearest sidewalls of substrate 20 by non-zero spacings S1, as discussed in preceding embodiments. The topmost ends of the reflowed photoresist blocks 30 may be lower than, level with, or slightly higher than the top surface 20TS1 of substrate 20, depending on the etching rate ratio ER20/ER30 in the subsequent etching process.

In a subsequent process, etching process 40 is performed. In accordance with some embodiments, the etching is performed using an etching gas that may etch both of the reflowed photoresist blocks 30 and the substrate 20. The etching is also anisotropic, so that the profiles of the top surfaces of the reflowed photoresist blocks 30 are transferred to the resulting micro lenses. The reflowed photoresist blocks 30 are fully consumed during the etching process 40.

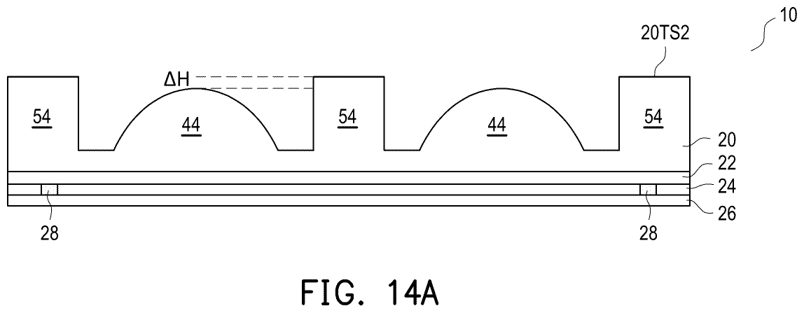

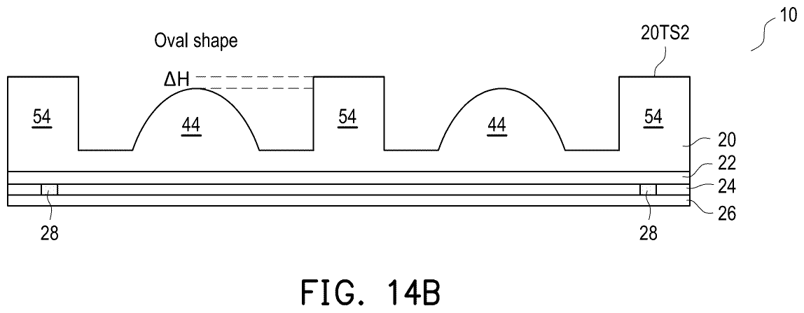

Micro lenses 40 are formed, as shown in FIGS. 14A and 14B, respectively, in which photoresist blocks 30 have rounded shape and oval shape, respectively. In the meantime, protection walls 54 are lowered due to the etching process 40.

The etching gas is selected to adjust the ratio ER20/ER30 to a proper value, which may be in the range between about 0.8 and about 1.2. With the proper etching gas being selected, the topmost ends of micro lenses 44 are slightly lower than the top surface 20TS2, for example, with the height difference ΔH being greater than 1 μm and smaller than about 20 μm, or may be smaller than about 100 μm or a slightly greater value. The structure as shown in FIG. 14A or 14B may have essentially the same structure and the same parameters as that in FIG. 9A, and thus the details are not repeated herein. The top-view shapes of micro lenses 44, recesses 52, and protection walls 54 may be essentially the same as that shown and discussed referring to FIGS. 9B and 9C, and are not repeated herein.

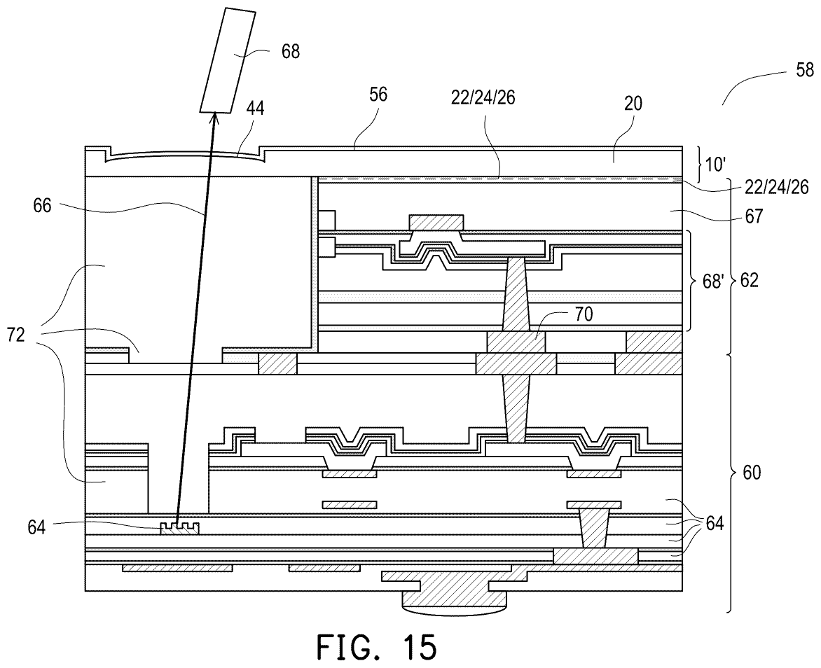

FIG. 15 illustrates a photonic package 58 in accordance with some embodiments, in which the die 10′ as shown in FIGS. 9A, 9B, and 9C are adopted. In accordance with some embodiments, photonic package 58 includes photonic die 60, electronic die 62 over and bonding to the photonic die 60, and die 10′ over and bonding to electronic die 62. The bonding of die 10′ to the electronic die 62 may be through fusion bonding, while the bonding of electronic die 62 to the photonic die 60 may be through a bonding (which includes metal-to-metal direct bonding) and fusion bonding.

In accordance with some embodiments, photonic die 60 may include photonic devices such as waveguides, grating couplers, edge couplers, modulators, and/or the like. For example, grating coupler 64 is illustrated as an example. The grating coupler 64 may be used for emitting or receiving a laser beam 66, which is emitted out of an optic fiber 68, or may be received by another coupler.

Electronic die 62 may be, for example, semiconductor devices, dies, or chips that communicate with photonic die 60 using electrical signals. Electronic die 62 includes semiconductor substrate 67, interconnect structure 68, and electrical connectors 70, which may be, for example, conductive pads, conductive pillars, or the like.

Electronic die 62 may include integrated circuits for interfacing with photonic die 60, such as the circuits for controlling the operation of photonic die 60. For example, electronic die 62 may include controllers, drivers, amplifiers, the like, or combinations thereof. Electronic die 62 may also include a CPU. In accordance with some embodiments, electronic die 62 includes the circuits for processing electrical signals received from photonic die 60. Electronic die 62 may also control high-frequency signaling of photonic die 60 according to electrical signals (digital or analog) received from another device or die, in accordance with some embodiments. In accordance with some embodiments, electronic die 62 may be an electronic integrated circuit (EIC) or the like that provides Serializer/Deserializer (SerDes) functionality. In this manner, electronic die 62 may act as part of an I/O interface between optical signals and electrical signals.

Die 10′ may have micro lenses 44, as discussed above. The formation process may be essentially the same as discussed in preceding embodiments. In accordance with some embodiments, the micro lenses 44 are formed after a reconstructed wafer is formed by bonding and encapsulating a plurality of electronic dies to a photonic wafer, and after wafer 10 (FIG. 1) is bonded to the reconstructed wafer. The processes of forming the micro lenses are performed on the resulting wafer that includes the wafer 10 and the reconstructed wafer. In accordance with alternative embodiments, the die 10′ are formed using the processes as discussed in preceding embodiments, and then the respective wafer 10 is bonded to a package (or a reconstructed wafer) that includes the photonic die(s) 60 and electronic die(s) 62.

Micro lens 44 as shown in FIG. 14A or 14B has the function of converging laser beam 66, which travels through the transparent dielectric layers 72 in the optical path. Accordingly, optical fiber 68 and photonic die 64 are used to pass optical signals.

The embodiments of the present disclosure have some advantageous features. By performing two etching processes, there is no need to form a hard mask on the substrate, forming the rounded photoresist through openings in the hard mask, and etching the substrate using the hard mask to define boundaries of the micro lenses. If the hard mask is used, the hard mask throughout a wafer may have thickness non-uniformity. This transfers to the wafer-level non-uniformity of the size and the shape of the resulting micro lenses. In accordance with the embodiments of the present disclosure, since no hard mask is used, the non-uniformity problem will not occur.

In accordance with some embodiments of the present disclosure, a method comprises forming sacrificial blocks on a substrate; reflowing the sacrificial blocks; performing a first etching process to etch both of the sacrificial blocks and the substrate until parts of the substrate that are etched to form micro lenses; forming a patterned etching mask; and performing a second etching process to etch the substrate, wherein at a time after both of the first etching process and the second etching process have been performed, the micro lenses are in recesses of the substrate.

In an embodiment, when the first etching process is performed, first top surfaces of the substrate directly underlying the sacrificial blocks are coplanar with second top surfaces of the substrate that are between neighboring ones of the sacrificial blocks. In an embodiment, when the first etching process is performed, first top surfaces of the substrate directly underlying the sacrificial blocks are lower than an additional top surface of the substrate. In an embodiment, the sacrificial blocks comprise a first photoresist. In an embodiment, the patterned etching mask comprises a second photoresist, and wherein the first photoresist and the second photoresist are formed of different photoresist materials.

In an embodiment, after both of the first etching process and the second etching process, the substrate comprises some portions forming protection walls, with the recesses being between the protection walls. In an embodiment, topmost ends of the micro lenses are lower than top surfaces of the protection walls. In an embodiment, the micro lenses are laterally spaced apart from nearest portions of the protection walls by spacings. In an embodiment, the spacings between the micro lenses and the nearest portions of the protection walls are greater than about 5 μm. In an embodiment, some parts of the substrate directly under the spacings have planar to surfaces. In an embodiment, the sacrificial blocks are in physical contact with the substrate.

In accordance with some embodiments of the present disclosure, a structure comprises a substrate comprising a transparent material; a plurality of protection walls forming a grid in a top view of the substrate, wherein the substrate comprises top surfaces; and a plurality of micro lenses in grid openings of the grid formed of the plurality of protection walls, wherein topmost ends of the plurality of micro lenses are level with or lower than the top surfaces of the plurality of protection walls, and wherein the plurality of protection walls are spaced apart from respective closest ones of the plurality of micro lenses. In an embodiment, materials of the plurality of protection walls are same as materials of the plurality of micro lenses.

In an embodiment, portions of the substrate laterally between the plurality of protection walls and the plurality of micro lenses have substantially planar top surfaces. In an embodiment, spacings that separate the plurality of protection walls from nearest ones of the plurality of micro lenses are greater than about 5 μm. In an embodiment, the topmost ends of the plurality of micro lenses are lower than the top surfaces of the plurality of protection walls. In an embodiment, the substrate comprises silicon.

In accordance with some embodiments of the present disclosure, a structure comprises a photonic package comprising a photonic die; and an electronic die on the photonic die; and a transparent substrate over the photonic package, wherein the transparent substrate comprises a recess at a top surface of the transparent substrate; a micro lens in the recess; and a portion of the transparent substrate surrounding the micro lens, wherein the recess is wider than the micro lens. In an embodiment, a portion of the transparent substrate surrounding the micro lens forms a full ring, and wherein a top-view shape of the full ring is different from a top-view shape of the micro lens. In an embodiment, the portion of the transparent substrate surrounding the micro lens comprises a first top surface higher than a second top surface of the micro lens.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming sacrificial blocks on a substrate;
reflowing the sacrificial blocks;
performing a first etching process to etch both of the sacrificial blocks and the substrate until parts of the substrate that are etched to form micro lenses;
forming a patterned etching mask; and
performing a second etching process to etch the substrate, wherein at a time after both of the first etching process and the second etching process have been performed, the micro lenses are in recesses of the substrate.

2. The method of claim 1, wherein when the first etching process is performed, first top surfaces of the substrate directly underlying the sacrificial blocks are substantially coplanar with second top surfaces of the substrate that are between neighboring ones of the sacrificial blocks.

3. The method of claim 1, wherein when the first etching process is performed, first top surfaces of the substrate directly underlying the sacrificial blocks are lower than an additional top surface of the substrate.

4. The method of claim 1, wherein the sacrificial blocks comprise a first photoresist.

5. The method of claim 4, wherein the patterned etching mask comprises a second photoresist, and wherein the first photoresist and the second photoresist are formed of different photoresist materials.

6. The method of claim 1, wherein after both of the first etching process and the second etching process, the substrate comprises some portions forming protection walls, with the recesses being between the protection walls.

7. The method of claim 6, wherein topmost ends of the micro lenses are lower than top surfaces of the protection walls.

8. The method of claim 6, wherein the micro lenses are laterally spaced apart from nearest portions of the protection walls by spacings.

9. The method of claim 8, wherein the spacings between the micro lenses and the nearest portions of the protection walls are greater than about 5 μm.

10. The method of claim 8, wherein some parts of the substrate directly under the spacings have planar to surfaces.

11. The method of claim 1, wherein the sacrificial blocks are in physical contact with the substrate.

12. A structure comprising:
a substrate;
a plurality of protection walls forming a grid in a top view of the substrate, wherein the substrate comprises top surfaces; and
a plurality of micro lenses in grid openings of the grid formed of the plurality of protection walls, wherein topmost ends of the plurality of micro lenses are level with or lower than the top surfaces of the plurality of protection walls, and wherein the plurality of protection walls are spaced apart from respective closest ones of the plurality of micro lenses.

13. The structure of claim 12, wherein materials of the plurality of protection walls are same as materials of the plurality of micro lenses.

14. The structure of claim 12, wherein portions of the substrate laterally between the plurality of protection walls and the plurality of micro lenses have substantially planar top surfaces.

15. The structure of claim 12, wherein spacings that separate the plurality of protection walls from nearest ones of the plurality of micro lenses are greater than about 5 μm.

16. The structure of claim 12, wherein the topmost ends of the plurality of micro lenses are lower than the top surfaces of the plurality of protection walls.

17. The structure of claim 12, wherein the substrate comprises silicon.

18. A structure comprising:
a photonic package comprising:
a first die; and
a second die on the first die; and
a substrate over the photonic package, wherein the substrate comprises:
a recess at a top surface of the substrate;
a micro lens in the recess; and
a portion of the substrate surrounding the micro lens, wherein the recess is wider than the micro lens.

19. The structure of claim 18, wherein a portion of the substrate surrounding the micro lens forms a full ring, and wherein a top-view shape of the full ring is different from a top-view shape of the micro lens.

20. The structure of claim 18, wherein the portion of the substrate surrounding the micro lens comprises a first top surface higher than a second top surface of the micro lens.
